(19) United States
(12) Patent Application Publication
(10) Pub. No.: US 2024/0076496 A1
(43) Pub. Date: Mar. 7, 2024

(54) Thermally Conductive Silicone Composition

(71) Applicant: Henkel AG & Co. KGaA, Duesseldorf (DE)

(72) Inventors: Wentao Xing, Shanghai (CN); Yi Liu, Shanghai (CN); Xiaolong Hu, Shanghai (CN)

(21) Appl. No.: 18/505,184

(22) Filed: Nov. 9, 2023

Related U.S. Application Data
(63) Continuation of application No. PCT/CN2021/094078, filed on May 17, 2021.

(51) Int. Cl. C08L 83/04

(52) U.S. Cl. CPC C08L 83/04; C08L 2205/025

(57) ABSTRACT

The present invention provides a thermally conductive silicone composition comprising: (A) at least one alkenyl group-containing organopolysiloxane; (B) at least one organohydrogenpolysiloxane having at least two hydrogen atoms directly bonded to a silicon atom in the molecule; (C1) one or more silane surface-treated alumina particles having a D₅₀ particle size of at least 0.01 μm but no greater than 5 μm; (C2) one or more silane surface-treated alumina particles having a D₅₀ particle size of greater than 5 μm; (D) at least one silane coupling agent; and (E) at least one platinum-based curing catalyst; wherein component (C1) is present in an amount of less than 62% by weight based on the weight of the composition and the component (C2) is present in an amount of less than 80% by weight based on the weight of the composition, which features favorable combination of properties including good flowability, as well as high thermal conductivity and good lap shear strength when cured.

### TECHNICAL FIELD

The present invention relates to a thermally conductive silicone composition, and particularly relates to a thermally conductive silicone composition exhibiting good flowability, as well as high thermal conductivity and good lap shear strength when cured, the preparation method and use thereof.

### BACKGROUND OF THE INVENTION

At present, there is an increasing demand for thermally conductive silicone compositions exhibiting good flowability, as well as high thermal conductivity and good lap shear strength when cured in the design of printed circuit boards and hybrid ICs of the electronic elements such as transistors, integrated circuits, memory elements, or the like.

Such thermally conductive silicone compositions may be exemplified by the following: a thermally conductive silicone composition comprising an organopolysiloxane having vinyl groups, an organohydrogenpolysiloxane, a thermally conductive filler, aminosilane, an adhesion-imparting agent selected from epoxy silane or alkyl titanate, and a platinum-type catalyst. In order to improve thermal conductivity in a cured body obtained from such thermally conductive silicone compositions, the compositions must incorporate a large amount of thermally conductive fillers. However, an increase of the amount of such fillers not only impairs flowability and moldability of the composition but also deteriorates physical properties of cured products derived from such compositions. Another drawback is the low adhesion strength of the cured product to various types of substrates.

EP 1726622 A1 discloses a thermally conductive silicone composition comprising: (A) an organopolysiloxane having the formula of {(CH₂═CH)R¹₂SiO_{1/2}}_{L}(R₁SiO_{3/2})ₘ(R¹₂SiO)ₙ{O_{1/2}SiR¹₂—R²—SIR¹₍₃₋ₐ₎(OR³)ₐ}ₒ, wherein R¹ represents monovalent hydrocarbon groups, R² represents an oxygen atom or a bivalent hydrocarbon group, R³ represents an alkyl group, alkoxyalkyl group, alkenyl group, or acyl group, L and o represent numbers from 1 to 10, m represents a number from 0 to 10, n represents a number from 5 to 100, a represents an integer from 1 to 3, and when m=0, L+o=2 and R² is a bivalent hydrocarbon group, (B) a heat conductive filler, and (C) an organopolysiloxane other than the component (A). The component (B) is preferably in a D₅₀ particle size of within a range from 0.1 to 100 μm, and even more preferably from 0.1 to 50 μm. The composition shows favorable handling and moldability properties, and the cured product of the composition features a highly heat conductivity. However, the cured product of the thermally conductive silicone composition has relatively low adhesion strength (no larger than 1.5 MPa), which is not suitable for permanent bonding in electrical and electronic applications.

EP 1331248 A2 discloses a thermally conductive silicone composition comprising: (A) an organopolysiloxane with an average of at least 0.1 alkenyl groups bonded to silicon atoms within each molecule, (B) an organopolysiloxane with an average of at least 2 hydrogen atoms bonded to silicon atoms within each molecule, (C) a heat-conductive filler, (D) a platinum catalyst, and (E) a methylpolysiloxane having a hydrolyzable group and a vinyl group represented by a specific structure formula. However, likewise, the cured product of the thermally conductive silicone composition has relatively low adhesion strength (no larger than 1.4 MPa).

CN 105916957 A discloses a thermally conductive silicone composition comprising: (A) an addition-reaction-curable silicone resin composition having a viscosity at 25° C. of less than or equal to 100 Pa·s; (B) a thermally conductive filler having an average particle diameter of greater than or equal to 0.1 μm and less than 1 μm; and (C) a solvent having a boiling point of higher than or equal to 250° C. and lower than 350° C. The blending amount of the component (B) is from 100 to 500 parts by mass per 100 parts by mass of the component (A). The blending amount of the component (C) is from 5 to 20 parts by mass per 100 parts by mass of the component (A). The cured product of the thermally conductive silicone composition has desired adhesion strength but has a low thermal conductivity (no larger than 1.2 W/(m·K)).

EP 3666781 A1 discloses a thermally conductive silicone composition comprising: (A) organopolysiloxane having at least two alkenyl groups bonded to a silicon atom in a molecule; 100 parts by mass, (B) organohydrogenpolysiloxane having at least two hydrogen atoms directly bonded to a silicon atom in a molecule; the number of moles of hydrogen atoms directly bonded to a silicon atom is an amount to be 0.1 to 5.0 times the number of moles of alkenyl groups derived from the (A) component, (C) a heat conductive filler; 200 to 3000 parts by mass, (D) a platinum-based curing catalyst; an amount to be 0.1 to 1000 ppm in terms of the platinum group element mass relative to the (A) component, (E) an addition reaction control agent; an effective amount, and (F-1) the organic silicon compound according to claim 1; 0.01 to 200 parts by mass. The cured product of the thermally conductive silicone composition has desired adhesion strength, however, the composition has relatively high viscosity (larger than 300 Pa·s), which is not suitable for handleability and moldability.

In view of the above, it is an object of the present invention to provide a thermally conductive silicone composition that has a favorable combination of properties including good flowability (less than 100 Pa·s at 25° C.), as well as high thermal conductivity (no less than 1.6 W/(m·K)) and good lap shear strength (no less than 1.6 MPa), when cured.

### SUMMARY OF THE INVENTION

Disclosed herein is a thermally conductive silicone composition comprising:
(A) at least one alkenyl group-containing organopolysiloxane;
(B) at least one organohydrogenpolysiloxane having at least two hydrogen atoms directly bonded to a silicon atom in the molecule;
(C1) one or more silane surface-treated alumina particles having a D₅₀ particle size of at least 0.01 μm but no greater than 5 μm;
(C2) one or more silane surface-treated alumina particles having a D₅₀ particle size of greater than 5 μm;
(D) at least one silane coupling agent; and
(E) at least one platinum-based curing catalyst;
wherein component (C1) is present in an amount of less than 62% by weight based on the weight of the composition and the component (C2) is present in an amount of less than 80% by weight based on the weight of the composition.

Also disclosed herein is the method for preparing a thermally conductive silicone composition according to the present invention.

Also disclosed herein is the cured product of the thermally conductive silicone composition according to the present invention.

Also disclosed herein is the use of the thermally conductive silicone composition and the cured product of the thermally conductive silicone composition according to the present invention in manufacturing electronic devices.

Other features and aspects of the subject matter are set forth in greater detail below.

### DETAILED DESCRIPTION OF THE INVENTION

It is to be understood by one of ordinary skill in the art that the present invention is a description of exemplary embodiments only and is not intended as limiting the broader aspects of the present invention. Each aspect so described may be combined with any other aspect or aspects unless clearly indicated to the contrary. In particular, any feature indicated as being preferred or advantageous may be combined with any other feature or features indicated as being preferred or advantageous.

Unless specified otherwise, in the context of the present invention, the terms used are to be construed in accordance with the following definitions.

Unless specified otherwise, as used herein, the terms “a”, “an” and “the” include both singular and plural referents.

The terms “comprising” and “comprises” as used herein are synonymous with “including”, “includes” or “containing”, “contains”, and are inclusive or open-ended and do not exclude additional, non-recited members, elements or process steps.

The term “room temperature” as used herein refers to a temperature of about 20° C. to about 25° C., preferably about 25° C.

Unless specified otherwise, the recitation of numerical end points includes all numbers and fractions subsumed within the respective ranges, as well as the recited end points.

All references cited in the present specification are hereby incorporated by reference in their entirety.

Unless otherwise defined, all terms used in the present invention, including technical and scientific terms, have the meaning as commonly understood by one of the ordinary skilled in the art to which this invention belongs.

In one aspect, the present disclosure is generally directed to thermally conductive silicone composition comprising:
(A) at least one alkenyl group-containing organopolysiloxane;
(B) at least one organohydrogenpolysiloxane having at least two hydrogen atoms directly bonded to a silicon atom in the molecule;
(C1) one or more silane surface-treated alumina particles having a D₅₀ particle size of at least 0.01 μm but no greater than 5 μm;
(C2) one or more silane surface-treated alumina particles having a D₅₀ particle size of greater than 5 μm;
(D) at least one silane coupling agent; and
(E) at least one platinum-based curing catalyst;
wherein component (C1) is present in an amount of less than 62% by weight based on the weight of the composition and the component (C2) is present in an amount of less than 80% by weight based on the weight of the composition.

### (A) Alkenyl Group-Containing Organopolysiloxane

According to the present invention, the thermally conductive silicone composition comprises (A) at least one alkenyl group-containing organopolysiloxane.

As used herein, “alkenyl” refers to a radical of a straight-chain or branched hydrocarbon group having from 2 to 40 carbon atoms and one or more carbon-carbon double bonds (e.g., 1, 2, 3, or 4 double bonds) (“C₂₋₄₀ alkenyl”). In some embodiments, an alkenyl group has 2 to 30 carbon atoms (“C₂₋₃₀ alkenyl”) In some embodiments, an alkenyl group has 2 to 20 carbon atoms (“C₂₋₂₀ alkenyl”) In some embodiments, an alkenyl group has 2 to 10 carbon atoms (“C₂₋₁₀ alkenyl”) In some embodiments, an alkenyl group has 2 to 9 carbon atoms (“C₂₋₉ alkenyl”). In some embodiments, an alkenyl group has 2 to 8 carbon atoms (“C₂₋₈ alkenyl”). In some embodiments, an alkenyl group has 2 to 7 carbon atoms (“C₂₋₇ alkenyl”). In some embodiments, an alkenyl group has 2 to 6 carbon atoms (“C₂₋₆ alkenyl”). In some embodiments, an alkenyl group has 2 to 5 carbon atoms (“C₂₋₅ alkenyl”). In some embodiments, an alkenyl group has 2 to 4 carbon atoms (“C₂₋₄ alkenyl”). In some embodiments, an alkenyl group has 2 to 3 carbon atoms (“C₂₋₃ alkenyl”). In some embodiments, an alkenyl group has 2 carbon atoms (“C₂ alkenyl”). The one or more carbon-carbon double bonds can be internal (such as in 2-butenyl) or terminal (such as in 1-butenyl). Examples of C₂₋₄ alkenyl groups include ethenyl (C₂), 1-propenyl (C₃), 2-propenyl (C₃), 1-butenyl (C₄), 2-butenyl (C₄), butadienyl (C₄), and the like. Examples of C₂₋₆ alkenyl groups include the aforementioned C₂₋₄ alkenyl groups as well as pentenyl (C₅), pentadienyl (C₅), hexenyl (C₆), and the like. Additional examples of alkenyl include heptenyl (C₇), octenyl (C₈), octatrienyl (C₈), and the like. Unless otherwise specified, each instance of an alkenyl group is independently unsubstituted (an “unsubstituted alkenyl”) or substituted (a “substituted alkenyl”) with one or more substituents. In certain embodiments, the alkenyl group is an unsubstituted C₂₋₃₀ alkenyl. In certain embodiments, the alkenyl group is a substituted C₂₋₃₀ alkenyl.

In some embodiments, the component (A) can be represented by the general formula (1):

[(CH₂═CH)R¹R²SiO_{1/2}]_{M}[R³R⁴SiO_{2/2}]_{D}[R⁵SiO_{3/2}]_{T}[SiO_{4/2}]_{Q} (1)

wherein R¹, R², R³, R⁴ and R⁵, each independently represents an unsubstituted or substituted monovalent hydrocarbon group; and M represents a number ranging from larger than 0 and less than 1, D, T, and Q each independently represents a number ranging from 0 to less than 1, provided that the sum of M, D, T and Q is 1.

In some embodiments, the unsubstituted or substituted monovalent hydrocarbon group in the general formula (1) is selected from straight-chain alkyl groups, preferably selected from methyl group, ethyl group, n-propyl group, n-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, n-nonadecyl group, and n-eicosyl group; branched-chain alkyl groups, preferably selected from isopropyl group, t-butyl group, isobutyl group, 2-methylundecyl group, and 1-hexylheptyl group; cyclic alkyl groups, preferably selected from a cyclopentyl group, cyclohexyl group, and cyclododecyl group; alkenyl groups, preferably selected from vinyl group, ally) group, butenyl group, pentenyl group, and hexenyl group; aryl groups, preferably selected from a phenyl group, tolyl group, and xylyl group; aralkyl groups, preferably selected from a benzyl group, phenethyl group, and 2-(2,4,6-trimethylphenyl)propyl group; and halogenated alkyl groups, preferably selected from 3,3,3-trifluoropropyl group and 3-chloropropyl group; preferably selected from straight-chain alkyl groups, alkenyl groups, and aryl groups; and more preferably selected from methyl group, ethyl group, vinyl group and phenyl groups.

In preferred embodiments, in the above general formula (1), both T and Q are 0, M and D are not 0, and the sum of M and D is 1.

In more preferred embodiments, in the above general formula (1), M ranges from 0.01 to 0.05, D ranges from 0.95 to 0.99, T and Q are 0, and the sum of M and D is 1.

Specific examples of the component (A) include the alkenyl group-containing organopolysiloxanes represented by the formulae as below:

[(CH₂═CH)(CH₃)₂SiO_{1/2}]^{0.012}[(CH₃)₂SiO_{2/2}]_{0.988}

[(CH₂═CH)(CH₃)₂SiO_{1/2}]_{0.040}[(CH₃)₂SiO_{2/2}]_{0.960}

[(CH₂═CH)(CH₃)₂SiO_{1/2}]_{0.028}[(CH₃)₂SiO_{2/2}]_{0.972}

[(CH₂═CH)(CH₃)₂SiO_{1/2}]_{0.019}[(CH₃)₂SiO_{2/2}]_{0.981.}

The functionality content of alkenyl groups in the component (A) is preferably in the range of from 0.1 to 1.0 mmol/g, more preferably from 0.1 to 0.6 mmol/g.

The viscosity at 25° C. of the component (A) is preferably in the range of from 50 to 100,000 mPa·s, and more preferably from 100 to 50,000 mPa·s.

There are no particular restrictions on the molecular weight of component (A), preferably in the range of from 3000 to 20,000 g/mol.

The component (A) may be used either alone, or in combinations of two or more different compounds.

Such alkenyl group-containing organopolysiloxane can be produced using conventionally known methods. In a typical production method, the alkenyl group-containing organopolysiloxane is produced by conducting an equilibration reaction of an organocyclooligosiloxane and a hexaorganodisiloxane in the presence of either an alkali or acid catalyst.

Examples of commercially available products of the component (A) include RH-Vi500E, RH-Vi70E, RH-Vi100E available from Zhejiang Runhe Organicsilicone New Material Co., Ltd, and Andisil® VS 200 from AB Specialty Silicones.

According to the present invention, the component (A) is present in an amount of from 1% to 20%, preferably 2% to 15% by weight, based on the total weight of the composition.

### (B) Organohydrogenpolvsiloxane

According to the present invention, the thermally conductive silicone composition also comprises (B) at least one organohydrogenpolysiloxane having at least two hydrogen atoms directly bonded to a silicon atom in the molecule, which works as a crosslinking agent to the component (A).

In one embodiment, the organohydrogenpolysiloxane has two or more —Si—H groups in one molecule. The —Si—H groups in the component (B) and alkenyl groups in the component (A) are added by a hydrosilylation reaction promoted by (E) platinum-based curing catalyst described below to generate a three-dimensional network structure having a crosslinked structure.

The component (B) may have at least two, and preferably three or more —Si—H groups per molecule, and these —Si—H groups may be positioned at the terminals of the molecular chain, at non-terminal positions, or at both these positions.

In preferred embodiments, the component (B) can be represented by the general formula (2):

[R⁶R⁷R⁸SiO_{1/2}]_{M′}[R⁹R¹⁰SiO_{2/2}]_{D′}[R¹¹SiO_{3/2}]_{T′}[SiO_{4/2}]_{Q′}, (2),

wherein R₆, R⁷, R⁸, R⁹, R¹⁰ and R¹¹ each independently represents an unsubstituted or substituted monovalent hydrocarbon group or hydrogen with the proviso that at least two of R⁶, R⁷, R⁸, R⁹, R¹⁰ and R¹¹ are hydrogen atoms directly bonded to a silicon atom in the molecule; and M′, D′, T′, and Q′ each represents a number ranging from 0 to less than 1, provided that the sum of M′, D′, T′ and Q′ is 1.

Suitable examples of the unsubstituted or substituted monovalent hydrocarbon group in the general formula (2) is selected from straight-chain alkyl groups, preferably selected from methyl group, ethyl group, n-propyl group, n-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, n-nonadecyl group, and n-eicosyl group; branched-chain alkyl groups, preferably selected from isopropyl group, t-butyl group, isobutyl group, 2-methylundecyl group, and 1-hexylheptyl group; cyclic alkyl groups, preferably selected from a cyclopentyl group, cyclohexyl group, and cyclododecyl group; alkenyl groups, preferably selected from vinyl group, allyl group, butenyl group, pentenyl group, and hexenyl group; aryl groups, preferably selected from a phenyl group, tolyl group, and xylyl group; aralkyl groups, preferably selected from a benzyl group, phenethyl group, and 2-(2,4,6-trimethylphenyl)propyl group; and halogenated alkyl groups, preferably selected from 3,3,3-trifluoropropyl group and 3-chloropropyl group; preferably selected from straight-chain alkyl groups, alkenyl groups, and aryl groups; and more preferably selected from methyl group, ethyl group, vinyl group and phenyl groups.

The functionality content of —Si—H groups in the component (B) is preferably in the range of from 0.1 to 10.0 mmol/g, more preferably from 0.1 to 5 mmol/g.

In preferred embodiments, the number of moles of the —Si—H groups contained in the component (B) is preferable in an amount that 0.1 to 5.0 times the number of moles of the alkenyl groups derived from the component (A).

The viscosity at 25° C. of the component (B) is preferably in the range of from 1 to 100,000 mPa·s, and preferably from 1 to 5,000 mPa·s.

There are no particular restrictions on the molecular weight of component (B), preferably in the range of from 2000 to 20,000 g/mol.

The component (B) may be used either alone, or in combinations of two or more different compounds.

In preferred embodiments, in the above general formula (2), both T′ and Q′ are 0, M′ and D′ are not 0, and the sum of M′ and D′ is 1.

In more preferred embodiments, in the above general formula (2), M′ ranges from 0.01 to 0.05, D′ ranges from 0.95 to 0.99, T′ and Q′ are 0, and the sum of M and D is 1.

Specific examples of the component (B) include the organopolysiloxanes represented by the formulae as below:

[H(CH₃)₂SiO_{1/2}]_{0.031}[H(CH₃)SiO_{2/2}]_{0.263}[(CH₃)SiO_{2/2}]_{0.706}

[(CH₃)₃SiO_{1/2}]0.028[H(CH₃)SiO_{2/2}]_{0.302}[(CH₃)₂SiO_{2/2}]_{0.670.}

The component (B) can be produced using conventionally known methods. Commercial products can be available as well. Examples of commercially available products of the component (B) include Crosslinker 210, Crosslinker 101 available from Evonik.

According to the present invention, the component (B) is present in an amount of from 0.5% to 20%, preferably from 1% to 10% by weight, based on the total weight of the composition.

### (C) Silane Surface-Treated Alumina Particles

According to the present invention, the thermally conductive silicone composition comprises (C₁) one or more silane surface-treated alumina particles having a D₅₀ particle size of at least 0.01 μm but no greater than 5 μm, and (C₂) one or more silane surface-treated alumina particles having a D₅₀ particle size of greater than 5 μm.

Herein, the “D₅₀ particle size” of the dispersion represents a median diameter in a volume-basis particle size distribution curve obtained by measurement with a laser diffraction particle size analyzer.

In preferred embodiment, the component (C₁) has a D₅₀ particle size of at least 0.1 μm but no greater than 2 μm, more preferably at least 0.1 μm but no greater than 1 μm.

In preferred embodiment, the component (C₂) has a D₅₀ particle size of greater than 7 μm, more preferably greater than 20 μm, even more preferably greater than 50 μm.

The shape of the component (C₁) and component (C₂) used in the present invention is not particularly limited. They may have spherical, rod-like, needle-like, disc-like, or amorphous shape, preferably spherical shape. In this description, the term “spherical” refers to a shape in which the entire surface is formed from a convex smooth surface. The term “rod-like” refers to a shape which is elongated along one axial direction, and in which the thickness is substantially constant along the longest axis. The term “needle-like”, is similar to “rod-like” in that the shape is elongated along one axial direction, but the shape also includes portions in which the thickness narrows towards the ends of the shape in the direction of the longest axis, whereas within the remaining portions, the thickness is substantially constant along the longest axis, meaning the end portions are pointed. The term “disc-like” refers to a flat shape which has a thickness in addition to a length for the longest axis and a length for the shortest axis. The term “amorphous” refers to shapes which cannot be classified as a specific shape.

According to the present invention, the component (C₁) and component (C₂) shall have silane surface treatment. The silane surface-treated alumina particles used in the present invention can be prepared by a dry method performed in a solventless system and a wet method performed in a solvent, and the most preferably surface treatment is performed in a solvent such as water or alcohol to completely perform the surface treatment; when a solvent is used, the organopolysiloxane and a solvent is mixed in a container, and then apply to the untreated alumina powder by a spray, afterwards, heating and drying the alumina powder to remove the solvent. Agglomeration may occur in the alumina powder during drying, and when a thermally conductive silicone composition is prepared from the agglomerated alumina powder, the fluidity may be reduced. For this reason, it is preferable to use silane surface-treated alumina powder prepared by a wet method performed in a solvent.

Suitable commercially available examples of the component (C1) are NSM-1H20 and NSM-1 SH2O from Bestry Performance Materials Co., Ltd.

Suitable commercially available examples of the component (C2) are BAH7H19, BAH5H1, BAH7OH12, BAH2OH4, from Bestry Performance Materials Co., Ltd., and HT-DAMO7 from Bergquist Company Zhuhai Limited.

According to the present invention, the component (C1) is present in an amount of less than 62% by weight, based on the total weight of the composition. If the component (C1) is above the aforementioned limit, the viscosity of the thermally conductive silicone composition will be too high to affect the flowability of the composition. Preferably, the component (C1) is present in an amount of from 5% to 55% by weight, more preferably from 10% to 50% by weight, even more preferably from 10% to 45% by weight, based on the total weight of the composition.

According to the present invention, the component (C2) is present in an amount of less than 80% by weight, based on the total weight of the composition. If the component (C2) is above the aforementioned limit, the lap shear strength of the cured product derived from the present composition will be greatly deteriorated. Preferably, the component (C2) is present in an amount of from 10% to 72% by weight, more preferably from 10% to 60% by weight, even more preferably from 10% to 45% by weight, based on the total weight of the composition.

In preferred embodiment, the mixing ratio in parts by mass of the component (C₁) and the component (C2) is from 0.2 to 5, preferably from 0.2 to 1.2.

### (D) Silane Coupling Agent

According to the present invention, the thermally conductive silicone composition comprises (D) at least one silane coupling agent.

Suitable silane coupling agent, which can be used in the present invention, includes, but not limited to, 3-methacryloxypropyltrimethoxysilane, methyltrimethoxysilane, 3-glycidoxypropyltrimethoxysilane, tetraethoxysilane, vinyltriethoxysilane, methyltris(methylethylketoxime)silane, vinyltriacetoxysilane, ethyl orthosilicate and the like.

Examples of commercially available examples of silane coupling include 3-methacryloxypropyltrimethoxysilane, methyltrimethoxysilane, 3-glycidoxypropyltrimethoxysilane from sinopharm.

According to the present invention, the component (D) is present in an amount of from 0.1% to 5% by weight, preferably from 0.1% to 3% by weight, based on the total weight of composition. If the quantity falls within this range, then adhesion strength of the cured product derived from the present composition can be more readily maintained.

### (E) Platinum-Based Curing Catalyst

According to the present invention, the thermally conductive silicone composition comprises (E) at least one platinum-based curing catalyst for accelerating the process of curing.

The component (E) is a catalyst for promoting an addition reaction of an alkenyl group derived from the component (A), and a —Si—H group derived from the component (B), and a catalyst well-known as a catalyst used in a hydrosilylation reaction may be used. Specific examples thereof include platinum group metal simple substance such as platinum (including platinum black), rhodium, and palladium; platinum chloride, chloroplatinic acid and chloroplatinate such as H₂PtCl₄·nH₂O, H₂PtCl₆·nH₂O, NaHPtCl₆·nH₂O, KaHPtCl₆·nH₂O, Na₂PtCl₆·H₂O, K₂PtCl₄·nH₂O, PtCl₄·nH₂O, PtCl₂, and Na₂HPtCl₄·nH₂O (here, in the formula, n is an integer of 0 to 6, preferably alcohol-modified chloroplatinic acid); complexes of chloroplatinic acid and olefin; ones obtained by supporting a platinum group metal such as platinum black and palladium on a support such as alumina, silica or carbon; a rhodium-olefin complex, chlorotris(triphenylphosphine)rhodium (Wilkinson catalyst); and, complexes of platinum chloride, chloroplatinic acid or chloroplatinate and a vinyl group-containing siloxane, in particular, a vinyl group-containing cyclic siloxane may be used.

Suitable commercially available examples of platinum-based curing catalysts include CAT-50 available from Avantor.

According to the present invention, the component (E) is present in an amount of from 1 ppm to 1000 ppm by weight, preferably from 1 ppm to 500 ppm by weight, based on the total weight of the composition.

### (F) Other Conductive Filler

In some embodiments, the thermally conductive silicon composition may further comprise at least one conductive filler different than component (C), including but not limited to fumed silica, precipitated silica, fumed titanium oxide, conductive fillers which does not have any surface treatment, and combinations thereof.

In preferred embodiments, the component (F) has a D₅₀ particle size of at least 0.1 μm but no greater than 100 μm, more preferably from 1 μm to 50 μm, even more preferably from 1 μm to 20 μm.

The shape of the component (F) used in the present invention is not particularly limited. They may have spherical, rod-like, needle-like, disc-like, or amorphous shape, preferably spherical shape.

Suitable commercially available examples of the component (F) include NSM-1, BA 2 from Bestry Performance Materials Co., Ltd., DAM 07 from Denka Corporation, SFADW-20 from by China Mineral Processing Limited, SJR 20 from AnHui Estone Materials Technology Co., Ltd, and HDK® 20 from Wacker Chemicals (Zhangjiagang) Co., Ltd.

In preferred embodiments, the thermally conductive silicon composition may not comprise component (F). If present, the component (F) is present in an amount of less than 40%, preferably no larger than 30% by weight, based on the total weight of composition.

### (G) Additive

In some embodiments, the thermally conductive silicon composition may further comprise additive selected from curing reaction inhibitor, pigments, dyes, fluorescent dyes, heat resistant additives, flame retardants, plasticizers, adhesion-imparting agents and combinations thereof, provided the inclusion of these additives does not impair the object of the present invention, curing reaction inhibitor in particularly.

Suitable examples of curing reaction inhibitor used in the present invention, including but not limited to an acetylene-based compound such as 2-methyl-3-butyn-2-ol, 2-phenyl-3-butyn-2-ol, or 1-ethynyl-1-cyclohexanol; an ene-in compound such as 3-methyl-3-penten-1-in, 3,5-dimethyl-3-hexen-1-in; a hydrazine-based compound; a phosphine-based compound; or a mercaptan-based compound, in order to enable regulation of the curing rate of the composition, thereby enabling an improvement in the flowability and workability properties.

Suitable commercially available examples of the curing reaction inhibitors include 3,5-dimethyl-1-hexyn-3-ol from Sigma-Aldrich Company.

In those cases where the composition of the present invention comprises curing reaction inhibitor, there are no particular restrictions on the quantity of the inhibitor, although a quantity within a range from 0.0001 to 1.0% by weight, based on the total weight of the composition is preferred.

In particular preferred embodiments, the thermally conductive silicone composition, based on the total weight of the composition, comprises:
(A) from 1% to 20% by weight, preferably from 2% to 15% by weight of at least one alkenyl group-containing organopolysiloxane;
(B) from 0.5% to 20% by weight, preferably from 1% to 10% by weight of at least one organohydrogenpolysiloxane having at least two hydrogen atoms directly bonded to silicon in the molecule,
(C1) from larger than 0 to less than 62% by weight, preferably from 5% to 55% by weight, more preferably from 10% to 50% by weight, even more preferably from 10% to 45% by weight of at least one silane surface-treated alumina powder having a D₅₀ particle size of at least 0.01 μm but no greater than 5 μm;
(C2) from larger than 0 to less than 80% by weight, preferably from 10% to 72% by weight, more preferably from 10% to 60% by weight, even more preferably from 10% to 45% by weight of at least one silane surface-treated alumina powder having a D₅₀ particle size of greater than 5 μm;
(D) from 0.1% to 5% by weight, preferably from 0.1% to 3% by weight of at least one silane coupling agent; and
(E) from 1 ppm to 1000 ppm by weight, preferably from 1 ppm to 500 ppm by weight of at least one platinum-based curing catalyst;
(F) from 0 to less than 40%, preferably no larger than 30% by weight of at least one thermally conductive filler other than component (C);
(G) from 0 to 1.0% by weight of additive.

A further aspect of the present invention relates to a method for preparing a thermally conductive silicone composition by mixing the said components simultaneously at room temperature for such as at least one hour, preferably at least two hours.

The thermally conductive silicone composition of the present invention has a good flowability with the thermally conductive filler loading of more than 80%, for example, having a viscosity less than 100 Pa·s, preferably less than 80 Pa·s, more preferably less than 50 Pa·s, even more preferably less than 30 Pa·s.

In preferred embodiments, the thermally conductive silicone composition can be cured at room temperature for from 2 to 7 days. Curing can be accelerated by applying heat, for example, by heating from 60 to 200° C. for from 30 minutes to 2 hours.

In the present invention, the thermally conductive silicone composition can be applied to the desired substrate by any convenient technique. It can be applied cold or be applied warm if desired. It can be applied by extruding or pasting it onto the substrate or other mechanical application methods such as a caulking gun. Generally, the thermally conductive silicone composition of the present invention is applied to one surface of a pair of substrates, and then the substrates are contacted each other to be bonded together. After application, the adhesive composition of the present invention is cured at room temperature, optionally followed by being curing at elevated temperature.

In another aspect of the present invention, provided is an article comprising a first substrate, a cured adhesive, and a second substrate bonded to the first substrate through the cured adhesive comprising a cured product derived from the curable adhesive composition according to any one of the preceding claims.

The first substrate and/or second substrate can be of a single material and a single layer or can include multiple layers of the same or different material. The layers can be continuous or discontinuous.

The substrates of the article descried herein can have a variety of properties including rigidity (e.g., rigid substrates (i.e., the substrate cannot be bent by an individual using two hands or will break if an attempt is made to bend the substrate with two hands), flexibility (e.g., flexible substrates (i.e., the substrate can be bent using no greater than the force of two hands), porosity, conductivity, lack of conductivity, and combinations thereof.

The substrates of the article can be in a variety of forms including, e.g., fibers, threads, yarns, wovens, nonwovens, films (e.g., polymer film, metallized polymer film, continuous films, discontinuous films, and combinations thereof), foils (e.g., metal foil), sheets (e.g., metal sheet, polymer sheet, continuous sheets, discontinuous sheets, and combinations thereof), and combinations thereof.

Useful substrate material used in the present invention include, e.g., polymer (e.g., polycarbonate, ABS resin (Acrylonitrile-Butadiene-Styrene resin), liquid crystal polymer, polyolefin (e.g., polypropylene, polyethylene, low density polyethylene, linear low density polyethylene, high density polyethylene, polypropylene, and oriented polypropylene, copolymers of polyolefins and other comonomers), polyether terephthalate, ethylene-vinyl acetate, ethylene-methacrylic acid ionomers, ethylene-vinyl-alcohols, polyesters, e.g. polyethylene terephthalate, polycarbonates, polyamides, e.g. Nylon-6 and Nylon-6,6, polyvinyl chloride, polyvinylidene chloride, cellulosics, polystyrene, and epoxy), polymer composites (e.g., composites of a polymer and metal, cellulose, glass, polymer, and combinations thereof), metal (aluminum, copper, zinc, lead, gold, silver, platinum, and magnesium, and metal alloys such as steel (e.g., stainless steel), tin, brass, and magnesium and aluminum alloys), carbon-fiber composite, other fiber-based composite, graphene, fillers, glass (e.g., alkali-aluminosilicate toughened glass and borosilicate glass), quartz, boron nitride, gallium nitride, sapphire, silicon, carbide, ceramic, and combinations thereof, preferably liquid crystal polymer, glass and combinations thereof.

The cured product of the thermally conductive silicone composition has a lap shear strength of more than 1.6 MPa with 100% Cohesive Failure mode on aluminum substrates, preferably more than 1.8 MPa, even more preferably more than 2.0 MPa according to ASTM D1002-05, and a thermal conductivity of no less than 1.6 W/(m·K), preferably no less than 1.8 W/(m·K), even more preferably larger than 2.0 W/(m·K), measured according to ASTM 1461.

As referred herein, “Cohesive Failure mode” refers to that the adhesive splits and portions of the adhesive remain adhered to each of the bonded surfaces. A failure mode wherein an adhesive is removed cleanly from the substrate is referred to as “Adhesive Failure mode”. An adhesive having Cohesive Failure mode is considered to be more robust than those having Adhesive Failure mode.

A further aspect in connection with the present invention relates to the use of the thermally conductive silicone composition and the cured product of the thermally conductive silicone composition according to the present invention in manufacturing electronic devices.

Exemplary electronic devices encompass computers and computer equipment, such as printers, fax machines, scanners, keyboards and the like; medical sensors; automotive sensors and the like; wearable electronic devices (e.g., wrist watches and eyeglasses), handheld electronic devices (e.g., phones (e.g., cellular telephones and cellular smartphones), cameras, tablets, electronic readers, monitors (e.g., monitors used in hospitals, and by healthcare workers, athletes and individuals), watches, calculators, mice, touch pads, and joy sticks), computers (e.g., desk top and lap top computers), computer monitors, televisions, media players, household appliances (e.g., refrigerators, washing machines, dryers, ovens, and microwaves), light bulbs (e.g., incandescent, light emitting diode, and fluorescent), and articles that include a visible transparent or transparent component, glass housing structures, protective transparent coverings for a display or other optical component.

Preferred in accordance with the invention is the use of the embodiments identified earlier on above as being preferred or more preferred, for the thermally conductive silicone composition of the present invention, where preferably two or more of the aspects or corresponding features described for the thermally conductive silicone composition are combined with one another.

### Examples

The following examples are intended to assist one skilled in the art to better understand and practice the present invention. The scope of the invention is not limited by the examples but is defined in the appended claims. All parts and percentages are based on weight unless otherwise stated.

### Raw Materials:

Component (A)
Component a-1: RH-Vi500E is vinyl terminated polydimethylsiloxane with a structure of [CH₂═CH(CH₃)₂SiO_{1/2}]_{0.012}[(CH₃)₂SiO_{2/2}]_{0.988}, manufactured by Zhejiang Runhe Chemical New Material Co., Ltd.
Component a-2: RH-Vi100E is vinyl terminated polydimethylsiloxane with a structure of [CH₂═CH(CH₃)₂SiO_{1/2}]_{0.028}[(CH₃)₂SiO_{2/2}]_{0.972}, manufactured by Zhejiang Runhe Chemical New Material Co., Ltd.
Component a-3: RH-Vi70E is vinyl terminated polydimethylsiloxane with a structure of [CH₂═CH(CH₃)₂SiO_{1/2}]0.040[(CH₃)₂SiO_{2/2}]_{0.960}, manufactured by Zhejiang Runhe Chemical New Material Co., Ltd.
Component a-4: Andisil® VS 200 is vinyl terminated polydimethylsiloxane with a structure of [CH₂═CH(CH₃)₂SiO_{1/2}]0.019[(CH₃)₂SiO_{2/2}]_{0.981}, manufactured by AB Specialty Silicone Company.
Component (B)
Component b-1: Crosslinker 101 is silicon-hydride terminated polydimethylsiloxane with a structure of [(CH₃)₃SiO_{1/2}]_{0.028}[H(CH₃)SiO_{2/2}]_{0.302}[(CH₃)₂SiO_{2/2}]_{0.670}, manufactured by Evonik Chemical Specialties (Shanghai) Co., Ltd.
Component b-2: Crosslinker 210 is silicon-hydride terminated polydimethylsiloxane with a structure of [H(CH₃)₂SiO_{1/2}]_{0.031}[H(CH₃)SiO_{2/2}]_{0.263}[(CH₃)₂SiO_{2/2}]_{0.706}, manufactured by Evonik Chemical Specialties (Shanghai) Co., Ltd.
Component (C1)
Component c1-1: NSM-1H20 is silane surface-treated alumina (D₅₀=0.89 μm), manufactured by Bestry Performance Materials Co., Ltd.
Component c1-2: NSM-1SH20 is silane surface-treated alumina (D₅₀=0.73 μm), manufactured by Bestry Performance Materials Co., Ltd.
Component (C2)
Component c2-1: BAH-7H19 is silane surface-treated alumina (D₅₀=7.57 μm), manufactured by Bestry Performance Materials Co., Ltd.
Component c2-2: HT-DAM07 is silane surface-treated alumina (D₅₀=7 μm), manufactured by The Bergquist Company Zhuhai Limited.
Component c2-3: BAH-5H1 is silane surface-treated alumina (D₅₀=5.45 μm), manufactured by Bestry Performance Materials Co., Ltd.
Component c2-4: BAH-70H12 is silane surface-treated alumina (D₅₀=71.80 μm), manufactured by Bestry Performance Materials Co., Ltd.
Component c2-5: BAH-20H4 is silane surface-treated alumina (D₅₀=21.56 μm), manufactured by Bestry Performance Materials Co., Ltd.
Component (D)
Component d-1: 3-Methacryloxypropyltrimethoxysilane was manufactured by Sinopharm Chemical Reagent Co., Ltd.
Component d-2: Methyltrimethoxysilane was manufactured by Sinopharm Chemical Reagent Co., Ltd.
Component d-3: 3-Glycidoxypropyltrimethoxysilane was manufactured by Sinopharm Chemical Reagent Co., Ltd.
Component (E)
Component e-1: CAT 50 is a platinum-divinyltetramethylsiloxane complex having 2.5% by weight of platinum, manufactured by Avantor.
Component (F)
Component f-1: NSM-1 is alumina powder (D₅₀=1.24 μm) having no surface treatment, manufactured by Bestry Performance Materials Co., Ltd.
Component f-2: DAM07 is alumina powder (D₅₀=8.2 μm) having no surface treatment, manufactured by Denka Corporation.
Component f-3: SFADW-20, alumina powder (D₅₀=20 μm) having no surface treatment, manufactured by China Mineral Processing Limited.
Component f-4: BA 2 is alumina powder (D₅₀=1.64 μm) having no surface treatment, manufactured by Bestry Performance Materials Co., Ltd.
Component f-5: SJR 20 is crystalline silica powder (D₅₀=20 μm), manufactured by AnHui Estone Materials Technology Co., Ltd.
Component f-6: HDK 20 is fumed silica, manufactured by Wacker Chemicals (Zhangjiagang) Co., Ltd.
Component (G)
Component g-1: 3,5-dimethyl-1-hexyn-3-ol was manufactured by Sigma-Aldrich Company.

### Test Methods:

### Viscosity:

The thermally conductive silicone composition of the present invention and samples of the comparative examples were allowed to stand for 24 hours in a constant-temperature chamber at 25° C., and the viscosity was then measured at a speed of 5 rpm at 25° C. using a viscometer with PP25 cone plate (product name: MCR301, manufactured by Anton-Paar Co., Ltd.).

The results are shown in Table 1 and Table 2. A smaller viscosity value indicates greater flowability for the thermally conductive silicone composition and superior handling characteristics. The viscosity of less than 100 Pa·s can be acceptable.

### Lap Shear Strength:

The lap shear strength of the cured samples of the present invention and comparative examples was determined according to ASTM D1002-05 using an Instron tensile tester (Model 5996) at crosshead speed of 10 mm/min, the test results were recorded in MPa.

The thermally conductive silicone composition was sandwiched between a pair of aluminium plates (Al 6063, manufactured by Donguang Baiside Company Limited), and then cured by heating at 160° C. for 30 minutes. The adhesion surface area was 25.4 mm×12.7 mm, and the thickness of the adhesive layer was 0.127 mm.

The cured sample having a lap shear strength of no less than 1.6 MPa with 100% Cohesive Failure mode can be acceptable.

### Thermal Conductivity Performance:

The thermally conductive silicone composition of the present invention and comparative examples were cured at 160° C. for 0.5 hour. The cured samples were cut into round pieces with 2 mm thickness and 12.7 mm diameter.

The thermal conductivity of cured samples of the present invention were tested by Laser Flash LFA447 (manufactured by NETZSCH Group) according to ASTM 1461. The thermally conductivity of no less than 1.6 W/(m·K) can be acceptable.

### Examples 1 to 13 (Ex. 1 to Ex. 13) and Comparative Examples 1 to 7 (CEx. 1 to CEx. 7)

The inventive and comparative thermally conductive silicone adhesive compositions were formed by mixing the components by weight percentage listed in the Table 1 and Table 2 at a room temperature for two hours in a 2-liter planetary mixer (manufactured by PC Laborsystem Co., Ltd.) and then cooled down to room temperature. The properties were tested using the methods stated above, and the results of evaluations are shown in Table 1 and Table 2.

TABLE 1

| Composition (wt %) | | Ex. 1 | Ex. 2 | Ex. 3 | Ex.4 | Ex. 5 | Ex. 6 | Ex. 7 | Ex. 8 | Ex. 9 | Ex. 10 | Ex. 11 | Ex. 12 | Ex. 13 |
|---|---|---|---|---|---|---|---|---|---|---|---|---|---|---|
| Component (A) | a-1 | 0 | 0 | 0 | 0 | 10.552 | 0 | 0 | 0 | 0 | 0 | 0 | 0 | 0 |
| | a-2 | 10.902 | 0 | 0 | 10.902 | 0 | 11.320 | 10.902 | 10.902 | 10.902 | 10.902 | 10.902 | 8.592 | 8.592 |
| | a-3 | 0 | 10.902 | 0 | 0 | 0 | 0 | 0 | 0 | 0 | 0 | 0 | 0 | 0 |
| | a-4 | 0 | 0 | 10.902 | 0 | 0 | 0 | 0 | 0 | 0 | 0 | 0 | 0 | 0 |
| Component (B) | b-1 | 0 | 0 | 0 | 0 | 2.300 | 0 | 0 | 0 | 0 | 0 | 0 | 0 | 0 |
| | b-2 | 3.100 | 3.100 | 3.100 | 3.100 | 0 | 3.100 | 3.100 | 3.100 | 3.100 | 3.100 | 3.100 | 3.060 | 3.060 |
| Component | c1-1 | 41.958 | 41.958 | 41.958 | 41.958 | 25.958 | 41.958 | 0 | 11.958 | 41.958 | 41.958 | 41.958 | 15.41 | 41.958 |
| (C1) | c1-2 | 0 | 0 | 0 | 0 | 0 | 0 | 41.958 | 0 | 0 | 0 | 0 | 0 | 0 |
| Component | c2-1 | 43.102 | 43.102 | 43.102 | 43.102 | 0 | 43.102 | 43.102 | 43.102 | 43.102 | 0 | 11.102 | 0 | 0 |
| (C2) | c2-2 | 0 | 0 | 0 | 0 | 0 | 0 | 0 | 0 | 0 | 0 | 0 | 72.000 | 35.302 |
| | c2-3 | 0 | 0 | 0 | 0 | 60.452 | 0 | 0 | 0 | 0 | 0 | 0 | 0 | 0 |
| | c2-4 | 0 | 0 | 0 | 0 | 0 | 0 | 0 | 0 | 0 | 0 | 0 | 0 | 10.350 |
| | c2-5 | 0 | 0 | 0 | 0 | 0 | 0 | 0 | 0 | 0 | 43.102 | 0 | 0 | 0 |
| Component (D) | d-1 | 0.200 | 0.200 | 0.200 | 0.400 | 0 | 0.400 | 0.200 | 0.200 | 0 | 0.200 | 0.200 | 0.200 | 0.200 |
| | d-2 | 0 | 0 | 0 | 0 | 0.200 | 0 | 0 | 0 | 0 | 0 | 0 | 0 | 0 |
| | d-3 | 0 | 0 | 0 | 0 | 0 | 0 | 0 | 0 | 0.200 | 0 | 0 | 0 | 0 |
| Component (E) | e-1 | 0.088 | 0.088 | 0.088 | 0.088 | 0.088 | 0.020 | 0.088 | 0.088 | 0.088 | 0.088 | 0.088 | 0.088 | 0.088 |
| Component (F) | f-1 | 0 | 0 | 0 | 0 | 0 | 0 | 0 | 30.000 | 0 | 0 | 0 | 0 | 0 |
| | f-3 | 0 | 0 | 0 | 0 | 0 | 0 | 0 | 0 | 0 | 0 | 32.000 | 0 | 0 |
| | f-6 | 0.200 | 0.200 | 0.200 | 0 | 0 | 0 | 0.200 | 0.200 | 0.200 | 0.200 | 0.200 | 0.200 | 0 |
| Component (G) | g-1 | 0.450 | 0.450 | 0.450 | 0.450 | 0.450 | 0.100 | 0.450 | 0.450 | 0.450 | 0.450 | 0.450 | 0.450 | 0.450 |

| | | | | | | | | | | | | | |
|---|---|---|---|---|---|---|---|---|---|---|---|---|---|
| Performance | | | | | | | | | | | | | |
| Filler loading | 85.5% | 85.5% | 85.5% | 85.5% | 86.7% | 85.5% | 85.5% | 85.5% | 85.5% | 85.5% | 85.5% | 87.9% | 87.9% |
| Viscosity (Pa · s) | 79.62 | 91.76 | 99.9 | 56.78 | 79.3 | 49.78 | 48.15 | 45.87 | 33.38 | 41.63 | 65.64 | 33.42 | 63.94 |
| Thermal Conductivity | 1.6 | 1.6 | 1.6 | 1.6 | 1.8 | 1.6 | 1.6 | 1.6 | 1.6 | 1.6 | 1.6 | 2.1 | 2.1 |
| (W/(m · K)) | | | | | | | | | | | | | |
| Lap Shear Strength | 1.9 | 2.2 | 2.1 | 1.8 | 1.6 | 2 | 2.4 | 1.8 | 1.6 | 2.1 | 1.6 | 1.6 | 2.3 |
| (MPa) | | | | | | | | | | | | | |
| LSS failure mode | 100% | 100% | 100% | 100% | 100% | 100% | 100% | 100% | 100% | 100% | 100% | 100% | 100% |
| | CF | CF | CF | CF | CF | CF | CF | CF | CF | CF | CF | CF | CF |

TABLE 2

| Composition (wt %) | | Cex. 1 | Cex. 2 | Cex. 3 | Cex. 4 | Cex. 5 | Cex. 6 | Cex. 7 |
|---|---|---|---|---|---|---|---|---|
| Component (A) | a-2 | 10.902 | 10.902 | 10.902 | 10.902 | 10.902 | 8.592 | 8.592 |
| Component (B) | b-2 | 3.100 | 3.100 | 3.100 | 3.100 | 3.100 | 3.060 | 3.060 |
| Component (C1) | c1-1 | 0 | 0 | 16.358 | 41.958 | 0 | 62 | 7.41 |
| Component (C2) | c2-1 | 43.102 | 0 | 0 | 0 | 0 | 0 | 0 |
| | c2-2 | 0 | 0 | 69.102 | 0 | 43.302 | 0 | 80 |
| | c2-5 | 0 | 0 | 0 | 0 | 0 | 25.41 | 0 |
| Component (D) | d-1 | 0.200 | 0.200 | 0 | 0.200 | 0.200 | 0.200 | 0.200 |
| Component (E) | e-1 | 0.088 | 0.088 | 0.088 | 0.088 | 0.088 | 0.088 | 0.088 |
| Component (F) | f-2 | 41.958 | 43.102 | 0 | 0 | 0 | 0 | 0 |
| | f-4 | 0 | 41.958 | 0 | 0 | 41.958 | 0 | 0 |
| | f-5 | 0 | 0 | 0 | 43.102 | 0 | 0 | 0 |
| | f-6 | 0.200 | 0.200 | 0 | 0.200 | 0 | 0.200 | 0.200 |
| Component (G) | g-1 | 0.450 | 0.450 | 0.450 | 0.450 | 0.450 | 0.450 | 0.450 |

| | | | | | | | |
|---|---|---|---|---|---|---|---|
| Performance | | | | | | | |
| Filler loading (wt %) | 85.5% | 85.5% | 85.5% | 85.5% | 85.5% | 87.9% | 87.9% |
| Viscosity (Pa · s) | 6.411 | 15.14 | 12.71 | 52.38 | 13.43 | 208 | 15.14 |
| Thermal Conductivity | 1.6 | 1.6 | 1.6 | 1.3 | 1.6 | 2.1 | 2.1 |
| (W/(m · K)) | | | | | | | |
| Lap Shear Strength | 0.6 | 1.4 | 1.3 | 1.8 | 1.4 | 3.4 | 1.4 |
| (MPa) | | | | | | | |
| LSS failure mode | 100% | 100% | 100% | 100% | 100% | 100% | 100% |
| | AF | AF | AF | CF | AF | CF | AF |

As can be seen from Table 1, the thermally conductive silicone adhesives of the present invention showed good flowability, as well as high thermal conductivity and good lap shear strength when cured.

However, as can be seen from Table 2, in the cases where the components of the present invention were not used like in Comparative Examples 1 to 7 (CEx.1 to CEx.7), it showed one or more unsatisfied properties compared to the thermally conductive silicone composition of the present invention.

Although some preferred embodiments have been described, many modifications and variations may be made thereto in light of the above teachings. It is therefore to be understood that the invention may be practiced otherwise than as specifically described without departing from the scope of the appended claims.

What is claimed is:

1. A thermally conductive silicone composition comprising:
(A) at least one alkenyl group-containing organopolysiloxane;
(B) at least one organohydrogenpolysiloxane having at least two hydrogen atoms directly bonded to a silicon atom in the molecule;
(C1) one or more silane surface-treated alumina particles having a D₅₀ particle size of at least 0.01 μm but no greater than 5 μm;
(C2) one or more silane surface-treated alumina particles having a D₅₀ particle size of greater than 5 μm;
(D) at least one silane coupling agent; and
(E) at least one platinum-based curing catalyst;
wherein component (C1) is present in an amount of less than 62% by weight based on the weight of the composition and the component (C2) is present in an amount of less than 80% by weight based on the weight of the composition.

2. The thermally conductive silicone composition according to claim 1, wherein the component (A) is represented by the general formula (1):
[(CH₂═CH)R¹R²SiO_{1/2}]_{M}[R³R⁴SiO_{2/2}]_{D}[R⁵SiO_{3/2}]_{T}[SiO_{4/2}]_{Q} (1)
wherein R¹, R², R³, R⁴ and R⁵, each independently represents an unsubstituted or substituted monovalent hydrocarbon group; and M represents a number ranging from larger than 0 and less than 1, D, T, and Q each independently represents a number ranging from 0 to less than 1, provided that the sum of M, D, T and Q is 1.

3. The thermally conductive silicone composition according to claim 2, wherein the unsubstituted or substituted monovalent hydrocarbon group in the general formula (1) is selected from a straight-chain alkyl group; a branched-chain alkyl group; a cyclic alkyl group; an alkenyl group; an aryl group; an aralkyl group; and a halogenated alkyl group.

4. The thermally conductive silicone composition according to claim 2, wherein the unsubstituted or substituted monovalent hydrocarbon group in the general formula (1) is selected from a methyl group, an ethyl group, a n-propyl group, a n-butyl group, a n-pentyl group, a n-hexyl group, a n-heptyl group, a n-octyl group, a n-nonyl group, a n-decyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a n-eicosyl group; an isopropyl group, a t-butyl group, an isobutyl group, a 2-methylundecyl group, a 1-hexylheptyl group; a cyclopentyl group, a cyclohexyl group, a cyclododecyl group; a vinyl group, an allyl group, a butenyl group, a pentenyl group, a hexenyl group; a phenyl group, a tolyl group, a xylyl group; a benzyl group, a phenethyl group, a 2-(2,4,6-trimethylphenyl)propyl group; a 3,3,3-trifluoropropyl group and a 3-chloropropyl group.

5. The thermally conductive silicone composition according to claim 2, wherein the unsubstituted or substituted monovalent hydrocarbon group in the general formula (1) is selected from a methyl group, an ethyl group, a vinyl group and a phenyl group.

6. The thermally conductive silicone composition according to claim 1, wherein the component (B) is represented by the general formula (2):
[R⁶R⁷R⁸SiO_{1/2}]_{M′}[R⁹R¹⁰SiO_{2/2}]_{D′}[R¹¹SiO_{3/2}]_{T′}[SiO_{4/2}]_{Q′} (2)
wherein R⁶, R⁷, R⁸, R⁹, R¹⁰ and R¹¹ each independently represents an unsubstituted or substituted monovalent hydrocarbon group or hydrogen with the proviso that at least two of R⁶, R⁷, R⁸, R⁹, R¹⁰ and R¹¹ are hydrogen atoms directly bonded to a silicon atom in the molecule; and M′, D′, T′, and Q′ each represents a number ranging from 0 to less than 1, provided that the sum of M′, D′, T′ and Q′ is 1.

7. The thermally conductive silicone composition according to claim 1, wherein the component (C1) has a D₅₀ particle size of at least 0.1 μm but no greater than 2 μm.

8. The thermally conductive silicone composition according to claim 1, wherein the component (C2) has a D₅₀ particle size of greater than 7 μm.

9. The thermally conductive silicone composition according to claim 1, wherein the component (A) is present in an amount of from 1% to 20% by weight, based on the total weight of the composition.

10. The thermally conductive silicone composition according to claim 1, wherein the component (B) is present in an amount of from 0.5% to 20% by weight, based on the total weight of the composition.

11. The thermally conductive silicone composition according to claim 1, wherein the component (C1) is present in an amount of from 5% to 55% by weight, based on the total weight of the composition.

12. The thermally conductive silicone composition according to claim 1, wherein the component (C2) is present in an amount of from 10% to 72% by weight, based on the total weight of the composition.

13. The thermally conductive silicone composition according to claim 1, wherein the component (D) is present in an amount of from 0.1% to 5% by weight, based on the total weight of the composition.

14. The thermally conductive silicone composition according to claim 1, wherein the component (E) is present in an amount of from 1 ppm to 1000 ppm by weight, based on the total weight of the composition.

15. The thermally conductive silicone composition according to claim 1, wherein the composition further comprises component (F) at least one thermally conductive filler other than component (C1) and component (C2) in an amount of less than 40%, based on the total weight of composition.

16. The thermally conductive silicone composition according to claim 1, wherein the composition further comprises component (G) at least one additive selected from curing reaction inhibitor, pigment, dye, fluorescent dye, heat resistant additive, flame retardant, plasticizer; adhesion-imparting agent, and combinations thereof.

17. A method for preparing the thermally conductive silicone composition according to claim 1, comprising:
providing a predetermined wt. % of the (A) at least one alkenyl group-containing organopolysiloxane;
providing a predetermined wt. % of the (B) at least one organohydrogenpolysiloxane having at least two hydrogen atoms directly bonded to a silicon atom in the molecule;
providing a predetermined wt. % of the (C₁) one or more silane surface-treated alumina particles having a D₅₀ particle size of at least 0.01 μm but no greater than 5 μm;
providing a predetermined wt. % of the (C₂) one or more silane surface-treated alumina particles having a D₅₀ particle size of greater than 5 μm;
providing a predetermined wt. % of the (D) at least one silane coupling agent;
providing a predetermined wt. % of the (E) at least one platinum-based curing catalyst; and
mixing the provided components simultaneously at room temperature.

18. A cured product of the thermally conductive silicone composition according to claim 1.

19. An electronic device comprising the thermally conductive silicone composition according to claim 1.
